(19) United States
(12) Patent Application Publication
(10) Pub. No.: US 2026/0305442 A1
(43) Pub. Date: Oct. 1, 2026

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/478,264

(22) PCT Filed: Apr. 17, 2024
(86) PCT No.: PCT/JP2024/015215

§ 371 Date: Oct. 24, 2025

(30) Foreign Application Priority Data
Apr. 28, 2023 (JP) 2023-074801

(51) Int. Cl. H10W 72/30; H10W 90/00; H10W 90/10

(52) U.S. Cl. CPC H10W 72/331; H10W 90/10; H10W 90/733

(57) ABSTRACT

An electronic module includes an electronic element, an internal connection terminal electrically connected with the electronic element and having electrical conductivity, and a chip spacer formed between a lower end surface of the internal connection terminal and the electronic element. The chip spacer is bonded to the electronic element via an electrically conductive bonding material BM1, and a recess having a diameter larger than the internal connection terminal is formed on an upper surface of the chip spacer. According to the electronic module, the positional displacement between the internal connection terminal and the chip spacer is prevented and hence, a self-alignment effect can be enhanced as desired.

### RELATED APPLICATIONS

This application is a National Phase of International Application No. PCT/JP2024/015215 filed Apr. 17, 2024, which claims priority based on Patent Application 2023-074801 filed in Japan on Apr. 28, 2023, and the entire contents of the application are incorporated herein by reference.

### TECHNICAL FIELD

The present invention relates to an electronic module.

### BACKGROUND ART

Conventionally, there has been known electronic modules each including an electronic element (a semiconductor element, a semiconductor chip), and an internal connection terminal that connects an electrode of the electronic module with a wiring pattern on a board. On the other hand, there has been known an electronic module that includes an electronic element, a board on which the electronic element is mounted, a pin terminal that functions as an internal connection terminal that is connected to a wiring pattern on the board, and a lead frame that supports the pin terminal, and electrically connects an electrode of the electronic element and the pin terminal to each other (see patent document 1 described hereinafter). Among these types of electronic modules, there has been known an electronic module where an internal connection terminal is connected with an electrode of the electronic element instead of the wiring pattern. As such an electronic module, an electronic module is considered where a stress is relaxed by connecting the electronic element to the internal connection terminal via a chip spacer.

On the other hand, there has been also known an electronic module where an electronic element 320 is bonded to an upper surface of an insulation board 312 via a solder BM 30 as illustrated in FIG. 6, and a chip spacer 318 is bonded via a solder BM 20 to a lower end side of an internal connection terminal 334 that is made to pass through a through hole (not illustrated in the drawing) formed in a lead frame (not illustrated in the drawing).

### PRIOR ART LITERATURE

### Patent Literature

[Japanese Patent 1] No. 6850938

### SUMMARY OF INVENTION

### Technical Problem

However, in a bonding step of the internal connection terminal 334 and the chip spacer 318, the solder BM 20 between the internal connection terminal 334 and the chip spacer 318 flows out and hence, the positional displacement occurs between the internal connection terminal 334 and the chip spacer 318 when the solder is melted thus giving rise to a drawback that it is difficult for the electronic module to exhibit a desired self-alignment effect.

The present invention has been made in view of the above-mentioned drawbacks, and it is an object of the present invention to provide an electronic module that can enhance a self-alignment effect as desired by suppressing the positional displacement of the internal connection terminal and the chip spacer.

### Solution to Problem

An electronic module of the present invention includes an electronic element, an internal connection terminal electrically connected with the electronic element and having electrical conductivity, and a chip spacer formed between a lower end surface of the internal connection terminal and the electronic element. The chip spacer is bonded to the electronic element via an electrically conductive bonding material, and a recess having a diameter larger than the internal connection terminal is formed on an upper surface of the chip spacer.

### Advantageous Effects of the Present Invention

According to the electronic module of the present invention, the recess having a diameter larger than a diameter of the terminal is formed in a region that is an outer peripheral portion of an upper surface of the chip spacer and corresponds to an outer periphery of the terminal and hence, it is possible to provide an electronic module that can enhance a desired self-alignment effect by suppressing the positional displacement between the internal connection terminal and the chip spacer.

### BRIEF DESCRIPTION OF DRAWINGS

FIG. 1 is a perspective view illustrating an external appearance of an electronic module 100 according to a first embodiment.

FIG. 2A to FIG. 2C are views for illustrating a chip spacer according to the first embodiment. FIG. 2A is a plan view illustrating one pin terminal and a chip spacer of the electronic module according to the first embodiment. FIG. 2B is a longitudinal cross-sectional view of FIG. 2A, and FIG. 2C is a perspective view illustrating an external appearance of a chip spacer.

FIG. 3 is a view illustrating a cross-sectional structure of the electronic module 100 according to the first embodiment.

FIG. 4A and FIG. 4B are views illustrating a state of the pin terminal and the chip spacer when the pin terminal is rotated. FIG. 4A is a view illustrating a state when the pin terminal is rotated in a case where shapes of the pin terminal and the chip spacer are a quadrangular shape, FIG. 4B illustrates a state when the pin terminal is rotated in a case where the shapes of the pin terminal and the chip spacer are in a disk shape.

FIG. 5 is a view illustrating a cross-sectional structure of an electronic module 100 according to a second embodiment.

FIG. 6 is a view for illustrating an electronic module according to a prior art.

### DESCRIPTION OF EMBODIMENTS

Hereinafter, an electronic module according to the present invention is described. An embodiment described hereinafter is not intended to limit the invention called for in claims. Further, it is not always the case that various elements and all combinations of these elements described in the embodiment are indispensable for the present invention.

### First Embodiment

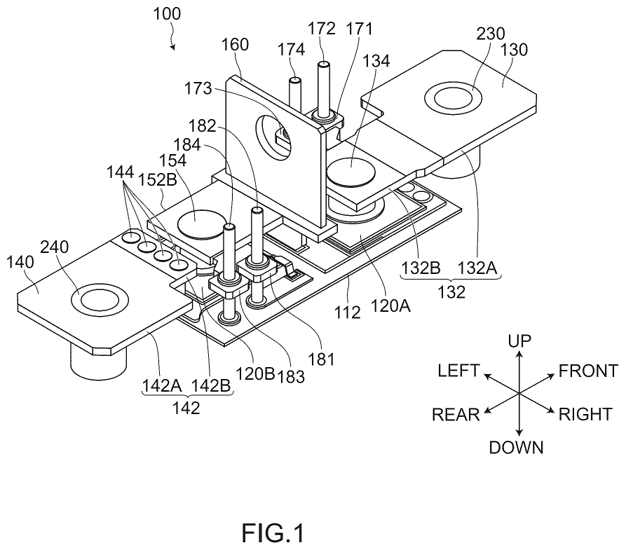

An electronic module 100 according to a first embodiment has, as illustrated in FIG. 1, an approximately rectangular parallelepiped shape that is elongated in a longitudinal direction and is flat in the vertical direction. The electronic module 100 includes an insulation board 112, electronic elements 120A, 120B, a first terminal 130, a second terminal 140, a third terminal 160, a first connection frame 132B, a second connection frame 142B, a third connection frame 152B, and a molding resin (not illustrated in the drawing).

The insulation board 112 is a ceramic board that is a direct copper bonding (DCB board) where a circuit wiring is formed on an upper surface of the ceramic board and a heat-radiation metal plate is formed on a lower surface (a back surface) of the ceramic board. Two electronic elements 120A, 120B are, for example, disposed on the circuit wiring formed on one surface of the insulation board 112. The insulation board 112 may be a printed circuit board or the like. The insulation board 112 is formed in a rectangular flat plate shape, and is disposed on a center portion of the electronic module 100 in the longitudinal direction, that is, the front-rear direction of the electronic module 100.

Two electronic elements 120A, 120B are respectively disposed on the circuit wiring formed on one surface of the insulation board 112. As the electronic element 120A, 120B may be formed of a semiconductor element, and a power metal-oxide-semiconductor field-effect transistor (MOSFET) can be used. However, an IGBT, a thyristor, a diode or other suitable elements can be used. The electronic element 120A, 120B includes an electrode not illustrated in the drawing on both surfaces of the semiconductor board. A source electrode and a gate electrode of the electronic element 120A, 120B are formed on an upper surface of the semiconductor board, and a drain electrode (not illustrated in the drawing) is formed on the lower surface of the semiconductor board.

In the electronic element 120A, the source electrode is connected to the first terminal 130 via a chip spacer 122, an internal connection terminal 134 and the first connection frame 132B. Further, the source electrode is connected with a pin terminal 172 that functions as a SENSE terminal via a wire, a circuit wiring or the like. The gate electrode is connected with the pin terminal 174 via the circuit wiring. The drain electrode is formed on a lower surface of the semiconductor board and is electrically connected with the circuit wiring. In the example illustrated in FIG. 1, the internal connection terminal 134 is a pin terminal having an circular cross-sectional shape.

In the electronic element 120B, the source electrode is connected with the drain electrode of the electronic element 120A on an upper side via a chip spacer (not illustrated in the drawing), an internal connection terminal 154, the third connection frame 152B and the circuit wiring and, at the same time, is connected with the third terminal 160 via a third connection frame 152B. The source electrode is connected with a pin terminal 182 that functions as a SENSE terminal via a wire, the circuit wiring or the like. The gate electrode is connected with a pin terminal 184 via the circuit wiring. The drain electrode is formed on a lower surface side of the semiconductor board, and is electrically connected with the second connection frame 142B via a circuit wiring. In the example illustrated in FIG. 1, the internal connection terminal 154 is a pin terminal having a circular cross-sectional shape.

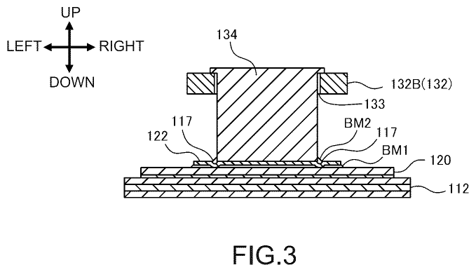

The first connection frame 132B and the first terminal 130 are integrally formed using the same plate member 132. That is, a portion of the plate member 132 that is embedded in the molding resin corresponds to the first connection frame 132B. The first connection frame 132B has a through hole 133 (see FIG. 3) that penetrates the first connection frame 132B in the vertical direction, and is electrically connected with the first terminal 130. The through hole 133 has a circular shape as viewed in the vertical direction. An upper end portion of the internal connection terminal 134 engages with the through hole 133 by fitting engagement, and the first connection frame 132B and the electrode of the electronic element 120A are connected with each other by the internal connection terminal 134. The shape of the through hole is not limited to a circular shape, and may be a polygonal shape such as a hexagonal shape.

The internal connection terminal 134 is formed of a metal member having a circular columnar shape. The internal connection terminal 134 electrically connects the electrode of the electronic element 120A and the first connection frame 132B to each other. For example, the internal connection terminal 134 is fixed to the first connection frame 132B by press-fitting.

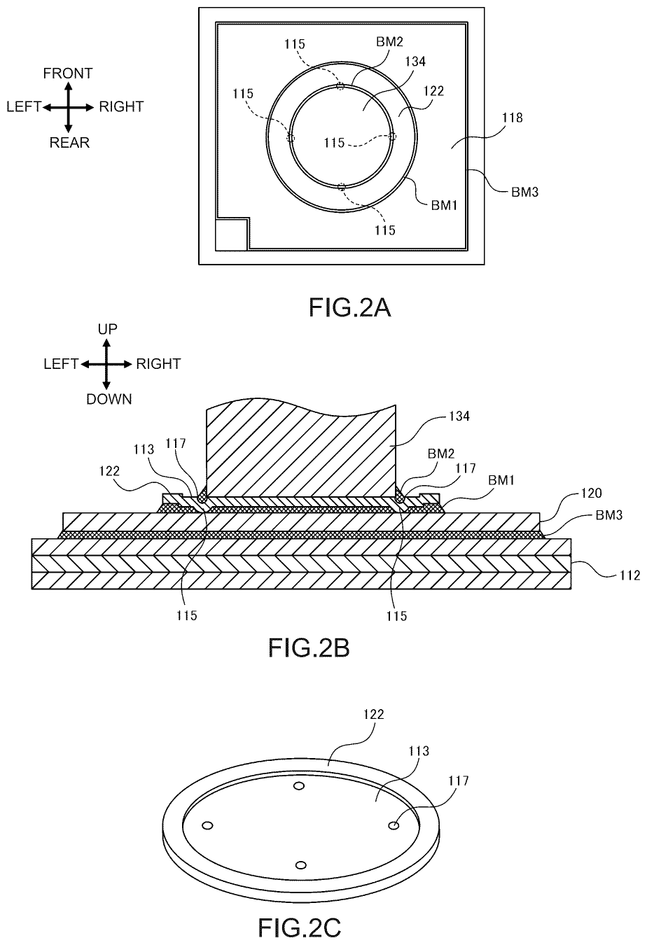

As illustrated in FIG. 2A and FIG. 2C, the chip spacer 122 is a thin flat-plate member having electrical conductivity (a copper plate in this embodiment), and is formed in a disk shape. The chip spacer 122 is disposed concentrically with the internal connection terminal 134. A diameter of the chip spacer 122 is set larger than a diameter of the internal connection terminal 134. An annular recess 113 having an outer diameter larger than a diameter of the internal connection terminal 134 is formed on an upper surface of the chip spacer 122. The chip spacer 122 is bonded to a lower surface of the internal connection terminal 134 via an electrically conductive bonding material (for example, a solder BM2) in the recess 113. A lower surface of the chip spacer 122 is bonded to an upper surface of the electronic element 120A (to be more specific, an electrode not illustrated in the drawing) via an electrically conductive bonding material (for example, a solder BM1). In the description made hereinafter, unless otherwise particularly necessary to distinguish these electronic elements, the description is made by giving 120 as the symbol of the electronic element for the sake of convenience of the explanation of the embodiment.

Protruding portions 115 are formed on a lower surface of the chip spacer 122. By bringing lower ends of the protruding portions 115 into contact with the electrode of the electronic element 120, it is possible to maintain a distance between a bottom of the chip spacer 122 and the electronic element 120 at a fixed value. Further, a solder thickness of the solder BM1 disposed between the chip spacer 122 and an electronic element 120 can be maintained at a fixed value. The recessed portions 117 that correspond to the protruding portions 115 are formed on an upper surface of the chip spacer 122. Although the protruding portions 115 are formed by applying a force in the vertically downward direction using pins (not illustrated in the drawing) from above at four positions, for example, of the recess 113 of the chip spacer 122, the protruding portions 115 may be formed by other methods, for example, using a die. Further, the recessed portions 117 can be formed when the protruding portions 115 are formed by applying a force in the vertically downward direction by the pins and hence, an external appearance shape of the recessed portion 117 becomes a shape corresponding to the shape of the protruding portion 115, and an outer diameter and a depth of the recessed portion 117 change corresponding to the shape of the protruding portion 115. Further, it is preferred that, with respect to the positions where the protruding portions 115 and the recessed portions 117 are formed, the protruding portions 115 and the recessed portions 117 are disposed outside an outer peripheral position of the internal connection terminal 134 and inside an outer diameter of the chip spacer 122, and the number of the protruding portions 115 and the number of recessed portions 117 are at least three or more. The reason that the number of protruding portions 115 and the number of the recessed portions 117 are set to three or more is to prevent the protruding portions 115 and the recessed portions 117 from affecting the upright erection of the chip spacer 122.

Also between a lower surface of the internal connection terminal 154 and the electronic element 120, in the same manner as described above, a chip spacer (not illustrated in the drawing) is disposed. However, the structure and the like of such a chip spacer are substantially equal to the above-mentioned chip spacer 122 and hence, the description of the chip spacer is omitted.

The second connection frame 142b IS electrically connected with the second terminal 140. The second connection frame 142B is embedded in the molding resin. In the electronic module 100, the second connection frame 142B is integrally formed with the second terminal 140 that is formed using the same plate member 142. That is, a portion of the plate member 142 embedded in the molding resin forms the second connection frame 142B.

The second connection frame 142B has four through holes (symbol being omitted) that penetrate the second connection frame 142B in the vertical direction. The through hole has a circular shape as viewed in the vertical direction. An upper end portion of the internal connection electrode 144 engages with each of four through holes. With the use of four internal connection electrodes 144, the second connection frame 142B and the electrodes (not illustrated in the drawing) of the electronic element 120B are connected with each other. The internal connection electrode 144 is fixed to the second connection frame 142B by press-fitting, for example. The number of the through holes described above and the number of internal connection electrodes 144 described above are not limited to four so long as required electricity is supplied, and may be set to a desired number more than one.

The third connection frame 152B is electrically connected with the third terminal 160. The third connection frame 152B may be arranged on the same plane as the first connection frame 132B and the second connection frame 142B.

The third connection frame 152B has through holes (symbol being omitted) that penetrate the third connection frame 152B in the vertical direction. The through hole is formed in a circular shape as viewed in the vertical direction. An upper end portion of the internal connection terminal 154 that functions as the internal connection electrode engages with the through hole by fitting engagement. With the use of the internal connection electrode 144, the third connection frame 152B and an electrode (not illustrated in the drawing) of the electronic element 120B are connected with each other. The internal connection terminal 154 is fixed to the third connection frame 152B by press-fitting, for example.

As illustrated in FIG. 1, the first terminal 130 is arranged on a front side of the electronic module 100 in the longitudinal direction. The first terminal 130 is formed of a flat-plate member having electrical conductivity, for example, the plate member 132A formed in a plate shape using a copper plate, for example. The first terminal 130 has a through hole (symbol being omitted) that penetrates the first terminal 130 in the vertical direction. The through hole is formed in a circular shape, for example as viewed in the vertical direction. The shape of the through hole is not limited to a circular shape, and may be a polygonal shape such as a hexagonal shape.

An upper end of a first cap nut 230 engages with the through hole by fitting engagement. In such a configuration, it is preferred that a height of an upper surface of the first cap nut 230 is equal to a height of an upper surface of the first terminal 130 or lower than the height of the upper surface of the first terminal 130.

A lower surface of the first terminal 130 and the first cap nut 230 are embedded in the molding resin. On the other hand, an upper surface of the first terminal 130 is exposed to the outside of the molding resin. An external connection member (not illustrated in the drawing) is disposed on the upper surface of the first terminal 130 exposed from the molding resin, and the external connection member is fixed by a bolt (not illustrated in the drawing) and hence, an electrical connection can be established between the first terminal 130 and the external connection member.

As illustrated in FIG. 1 to FIG. 3, the second terminal 140 is arranged on a rear side of the electronic module 100 in the longitudinal direction. The second terminal 140 is formed of a flat-plate member having electrical conductivity, for example, the plate member 142A formed in a plate shape using a copper plate, for example. The second terminal 140 has a through hole (symbol being omitted) that penetrates the second terminal 140 in the vertical direction. The through hole is formed in a circular shape, for example, as viewed in the vertical direction.

An upper end of a second cap nut 240 engages with the through hole by fitting engagement. In such a configuration, it is preferred that a height of an upper surface of the second cap nut 240 is equal to a height of an upper surface of the second terminal 140 or lower than the height of the upper surface of the second terminal 140.

A lower surface of the second terminal 140 and the second cap nut 240 are embedded in the molding resin. On the other hand, an upper surface of the second terminal 140 is exposed to the outside of the molding resin. An external connection member (not illustrated in the drawing) is disposed on the upper surface of the second terminal 140 exposed from the molding resin, and the external connection member is fixed by a bolt (not illustrated in the drawing) and hence, an electrical connection can be established between the second terminal 140 and the external connection member.

The electronic module 100 may also include a third terminal 160. The third terminal 160 is an arbitrary constitutional element. As illustrated in FIG. 1, the third terminal 160 is formed of a flat-plate member having electrical conductivity for example, and is formed of a copper plate. The third terminal 160 is arranged such that the longitudinal direction is a plate thickness direction, and is formed in an elongated shape with the vertical direction set as the longitudinal direction. The third terminal 160 includes: a portion that is disposed on an upper side of the molding resin and is exposed from the molding resin (hereinafter, referred to as “upper side portion”) ; and a portion that is covered by the molding resin (hereinafter, referred to as “lower side portion”).

A through hole (symbol being omitted) that penetrates the third terminal 160 in the longitudinal direction is formed in the upper side portion of the third terminal 160. With such a configuration, an external connection member (not illustrated in the drawing) can be fixed to the third terminal 160 by a bolt (not illustrated in the drawing) and a nut (not illustrated in the drawing). Further, one end of a cap nut (not illustrated in the drawing) may engage with the through hole by fitting engagement. With such a configuration, when the external connection member is fixed to the third terminal 160 by the bolt, the electrical connection between the third terminal 160 and the external connection member can be established with certainty. A lower side portion of the third terminal 160 is connected to electrodes (not illustrated in the drawing) of the electronic elements 120A, 120B.

### [Advantageous Effects Acquired by First Embodiment]

According to the electronic module 100 of the first embodiment, the annular recess 113 having an outer diameter larger than a diameter 44 the internal connection terminal 134 is formed on the chip spacer 122. With the formation of such a recess 113, it is possible to prevent the solder BM2 from flowing out between the upper surface of the chip spacer 122 and the lower surface of the internal connection terminal 134 to the outside in the radial direction.

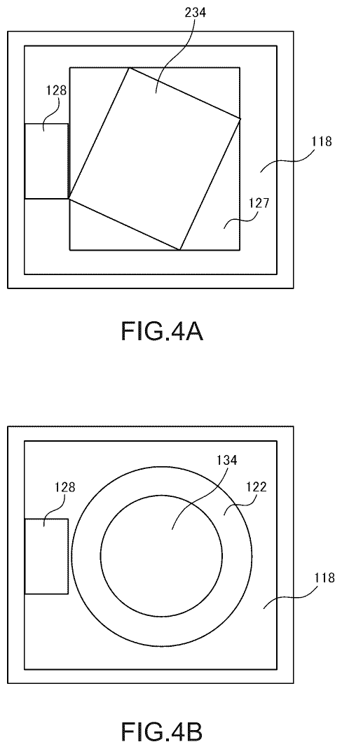

The chip spacer 122 formed in a disk shape is concentrically disposed with the internal connection terminal 134 (see FIG. 4B). Accordingly, compared to a case where a chip spacer 127 formed in a quadrangular shape, for example is disposed on the upper surface of the electronic element 120 and is disposed on a lower surface of the internal connection terminal 234 having a quadrangular shape (see FIG. 4A), it is possible to prevent the chip spacer 122 from being brought into contact with an electronic part 128 around the chip spacer 122 due to the rotational movement of the internal connection terminal 234 when a solder coagulates.

The protruding portions 115 are formed on the lower surface of the chip spacer 122. Accordingly, it is possible to realize the self-alignment of the chip spacer 122 toward an axis of the internal connection terminal 134 when the solder BM1 is coagulated due to the provision of the protruding portions 115.

Further, the recessed portions 117 are formed on the upper surface of the chip spacer 122. Accordingly, it is possible to prevent the solder BM2 from flowing out from between the upper surface of the chip spacer 122 and the lower surface of the internal connection terminal 134 toward the outside in the radial direction.

### Second Embodiment

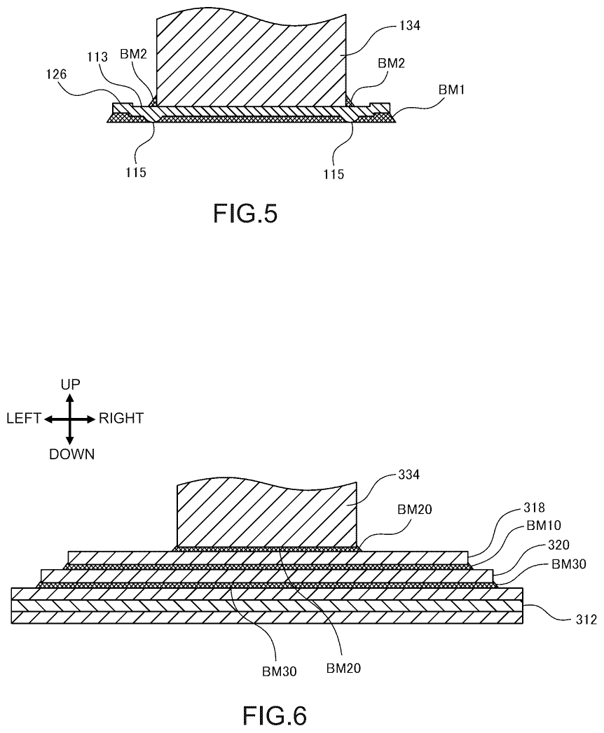

Hereinafter, an electronic module according to the second embodiment of the present invention is described with reference to FIG. 5. The second embodiment is substantially equal to the first embodiment except for a point that the recessed portions 117 in the above-mentioned first embodiment are not formed. Accordingly, the description is made only with respect to the different point, and the description of the substantially same portions is omitted. As illustrated in FIG. 5, only protruding portions 115 are formed on a chip spacer 126 by injection molding using a die without forming the recessed portions 117 illustrated in FIG. 2C. Even in a case where only the protruding portions 115 are formed without forming the recessed portions 117, an annular recess 113 having an outer diameter larger than a diameter of an internal connection terminal 134 is formed in the chip spacer 126.

Accordingly, by forming the recess 113 having an outer diameter larger than a diameter of the internal connection terminal 134 on the chip spacer 126, it is possible to prevent a solder BM2 from flowing out from between an upper surface of a chip spacer 122 and a lower surface of the internal connection terminal 134 toward the outside in the radial direction. Further, the protruding portions 115 are formed on the lower surface of the chip spacer 126. Accordingly, it is possible to realize the self-alignment of the chip spacer 126 toward an axis of the internal connection terminal 134 when the solder BM1 is coagulated due to the provision of the protruding portions 115.

1. An electronic module comprising:
an electronic element;
an internal connection terminal electrically connected with the electronic element and having electrical conductivity; and
a chip spacer formed between a lower end surface of the internal connection terminal and the electronic element, wherein
the chip spacer is bonded to the electronic element via an electrically conductive bonding material, and a recess having a diameter larger than the internal connection terminal is formed on an upper surface of the chip spacer.

2. The electronic module according to claim 1, wherein the internal connection terminal has a circular columnar shape, and the chip spacer has a disk shape.

3. The electronic module according to claim 1, wherein a protruding portion is formed on a lower surface of the chip spacer.

4. The electronic module according to claim 1, wherein a recessed portion is formed on an upper surface of the chip spacer.
